(19) United States
(12) Patent Application Publication
(10) Pub. No.: US 2009/0032921 A1
(43) Pub. Date: Feb. 5, 2009

(54) PRINTED WIRING BOARD STRUCTURE AND ELECTRONIC APPARATUS

(75) Inventor: Yuichi Koga, Hachioji-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/181,838

(22) Filed: Jul. 29, 2008

(30) Foreign Application Priority Data
Jul. 31, 2007 (JP) 2007-199343

(51) Int. Cl. H01L 23/495

(52) U.S. Cl. 257/676; 257/E23.031

(57) ABSTRACT

According to one embodiment, a printed wiring board structure includes first and second semiconductor packages each including a substrate, and a printed wiring board including first and second component mounting surfaces having a relationship given as front and back surfaces and an inter-chip connection part provided at one portion thereof, the inter-chip connection part being provided with a plurality of arrayed through conductors penetrating through the first and second component mounting surfaces, wherein the substrates of the first and second semiconductor packages are arranged on the printed wiring board in a positional relationship such that the substrates mounted on the component mounting surfaces are partially overlapped via the printed wiring board, the external connection electrodes provided on the substrates are arrayed on the overlapped portion and are conductively connected to the through conductors arrayed in the inter-chip connection part.

### CROSS-REFERENCE TO RELATED APPLICATIONS

This application is based upon and claims the benefit of priority from Japanese Patent Application No. 2007-199343, filed Jul. 31, 2007, the entire contents of which are incorporated herein by reference.

### BACKGROUND

1. Field

One embodiment of the present invention relates to a printed wiring board structure in which a semiconductor package having a semiconductor chip loaded on a substrate is mounted on the front and back surfaces of a printed wiring board.

2. Description of the Related Art

In an electronic apparatus such as personal computer, a circuit board is received as a main constituent component in a computer housing. The circuit board is mounted with a plurality of semiconductor packages each called a chip set including a CPU and peripheral circuits around the CPU. The circuit board mounted with the semiconductor packages requires high density wiring and high density mounting to achieve high speed signal processing and high performance. Recently, for example, PCI-Express and SATA (Serial-ATA) have been proposed as a technique of achieving the high speed signal processing. Specifically, a high-speed bus interface using a differential signal and a source-synchronous bus interface by source-synchronous transmission are frequently employed. In these interface circuits, a connection interface technique between semiconductor devices capable of achieving the high speed signal transmission is required.

Conventionally, the following technique has been proposed as the connection interface technique between semiconductor devices. According to the technique, pin assignment between the semiconductor devices is provided so that a mirror image symmetric relationship is established. In this way, the inter-pin wiring configuration between semiconductor devices is proposed in Jpn. Pat. Appln. KOKAI Publication No. 2001-24146, for example.

The foregoing mirror image pin assignment technique is applied to mounting of semiconductor devices on a flat surface of the substrate. In other words, these semiconductor devices are each arranged on one plane. For this reason, there is a problem to achieve substrate miniaturization and high density mounting of the devices on the substrate. In addition, a predetermined distance is required between the semiconductor devices on the substrate. For this reason, a wiring pattern having a predetermined wiring length is required in an inter-pin connection between semiconductor devices. As a result, there is a problem in adaptability to achieve high-speed bus connection between semiconductor devices.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a side view showing a printed wiring board structure according to a first embodiment of the present invention;

FIG. 2 is a top plan view showing the printed wiring board structure according to the first embodiment;

FIG. 3 is a sectional view showing a structure of a through conductor of the printed wiring board structure according to the first embodiment;

FIG. 4 is a sectional view showing another structure of a through conductor of the printed wiring board structure according to the first embodiment;

FIG. 5A is a plan view showing a further structure of a through conductor of the printed wiring board structure according to the first embodiment;

FIG. 5B is a side view showing the further structure of a through conductor of the printed wiring board structure shown in FIG. 5A;

FIG. 6 is a sectional view showing a still further structure of a through conductor of the printed wiring board structure according to the first embodiment;

FIG. 7 is a side view showing a modification of the printed wiring board structure according to the first embodiment;

FIG. 8 is a top plan view showing another modification of the printed wiring board structure according to the first embodiment; and

FIG. 9 is a perspective view showing the configuration of an electronic apparatus according to a second embodiment of the present invention.

### DETAILED DESCRIPTION

Various embodiments according to the present invention will be hereinafter described with reference to accompanying drawings. In general, according to one embodiment of the invention, a printed wiring board structure includes first and second semiconductor packages each including a substrate having one surface mounted with a semiconductor chip and the other surface mounted with a plurality of arrayed external connection electrodes, and a printed wiring board including first and second component mounting surfaces having a relationship given as front and back surfaces and an inter-chip connection part provided at one portion thereof, the inter-chip connection part being provided with a plurality of arrayed through conductors penetrating through the first and second component mounting surfaces, wherein the substrates of the first and second semiconductor packages are arranged on the printed wiring board in a positional relationship such that the substrates mounted on the component mounting surfaces are partially overlapped via the printed wiring board, the external connection electrodes provided on the substrates are arrayed on the overlapped portion and are conductively connected to the through conductors arrayed in the inter-chip connection part, and the first semiconductor package is mounted on the first component mounting surface while the second semiconductor package is mounted on the second component mounting surface.

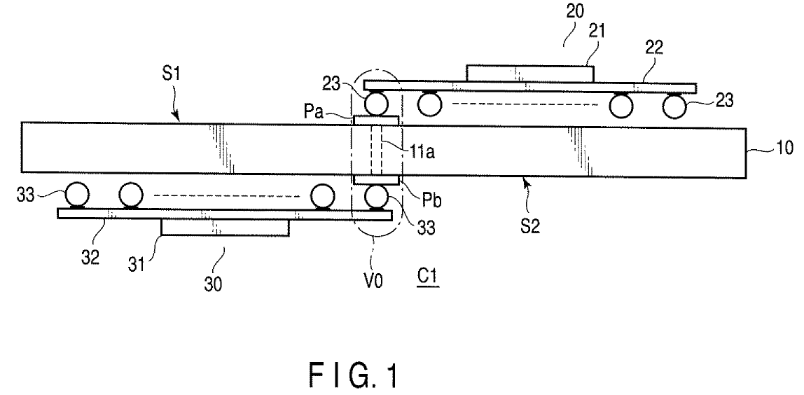

Printed wiring board structures mounted with semiconductor packages according to a first embodiment of the present invention will be described below with reference to FIG. 1 to FIG. 6. According to the first embodiment, a ball grid array (BGA) component is given as one example of the semiconductor package.

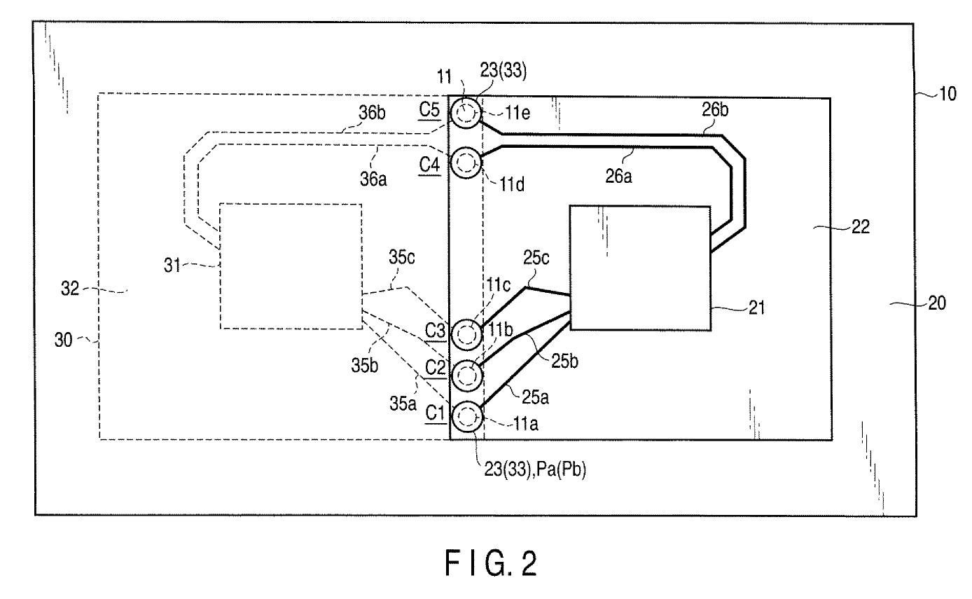

According to the first embodiment of the present invention, the printed wiring board structure mainly includes a multi-layer structure printed wiring board 10, a first semiconductor package (hereinafter, referred to as BAG component) 20 and a second semiconductor package (hereinafter, referred to as BAG component) 30. Specifically, as shown in FIG. 1 and FIG. 2, the printed wiring board 10 has the front and back component mounting surfaces S1, S2. The printed wiring board 10 further has an inter-chip connection part V0 in a selected area thereof. In this case, the part V0 is set at a center part of the board 10. In the inter-chip connection part V0, a plurality of through conductors penetrating between the foregoing component mounting surfaces S1, S2 are arrayed. The first and second semiconductor packages 20 and 30 are mounted on the front and back component mounting surfaces S1, S2 of the printed wiring board 10, respectively so that they are partially overlapped via the foregoing inter-chip connection part V0. These BGA components 20 and 30 are each a chip set configured to have a plurality of high-speed signal transmission lines assigned in a mirror image pin assignment manner.

The BGA component 20 is composed of a semiconductor chip or a die 21 and a substrate 22. One surface (front surface) of the substrate 22 is mounted with the semiconductor chip 21. The other surface (back surface) of the substrate 22 is provided with a plurality of solder balls 23 arrayed like a matrix. In this case, these solder balls 23 function as external connection electrodes. Similar to the foregoing BGA component 20, the BGA component 30 is composed of a semiconductor chip (die) 31 and a substrate 32. The front surface of the substrate 32 is mounted with the semiconductor chip 31. The back surface of the substrate 32 is provided with a plurality of solder balls 33 arrayed like a matrix In this case, these solder balls 33 function as external connection electrodes.

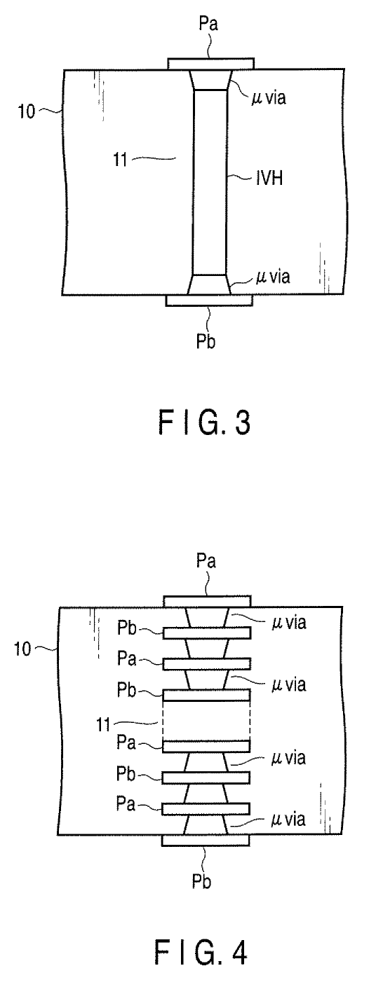

As shown in FIGS. 1 and 2, the BGA components 20 and 30 are respectively mounted on the front and back component mounting surfaces S1, S2 of the printed wiring board 10 in the following manner. Specifically, the substrates 22 and 32 each has four edges so that the substrates 22 and 32 are arranged in a positional relationship in which one edge portion of the substrate 22 is partially overlapped with one edge portion of the substrate 32. Two edges of the substrate 22 perpendicular and next to the overlapped one edge portion are arranged with corresponding those of the substrate 32 along a straight line, respectively, as shown in FIG. 2. Further, solder balls 23 and 33 provided at the overlapped portions are electro-conductively connected (soldered) to the through conductors 11a to 11e arrayed in the inter-chip connection part V0. Incidentally, the through conductor 11a to 11e each includes component mounting pads Pa and Pb soldered to the solder balls 23 and 33. The configuration of the through conductors 11a to 11e will be described later with reference to FIG. 3 to FIG. 6. The pads Pa and Pb shown in FIG. 1 are not shown in FIG. 2 for the sake of simplicity.

The BGA components 20 and 30 are respectively mounted on the front and back component mounting surfaces S1, S2 of the printed wiring board 10 based on the following positional relationship. Specifically, according to the structure shown in FIG. 1 and FIG. 2, the substrates 22 and 33 are partially overlapped at one edge portion. Of many solder balls 23 and 33 arrayed on respective back surfaces of the substrates 22 and 23, one-line solder balls 23 and 33 closest to each edge of the overlapped substrates 22 and 33 are overlapped in the inter-chip connection part V0. The inter-chip connection part V0 is provided at a position where the BGA components 20 and 30 are overlapped via the printed wiring board 10. The foregoing inter-chip connection part V0 makes high-speed bus connection by mirror image pin assignment as a bus connection interface between the BGA components 20 and 30.

In FIG. 2, linearly arranged solder balls 23 and 33 are overlapped in the inter-chip connection part V0 of the printed circuit board 10. Of these solder balls, linearly arranged five solder balls 23 and 33 are conductively soldered to the corresponding through conductors 11a to 11e in the inter-chip connection part V0 to form five conductive connections C1 to C5 at both ends of the conductors 11a to 11e. FIG. 1 shows the conductive connection C1. In FIG. 2, the pads Pa, Pb provided at both ends of the through conductors 11a shown in FIG. 1 are omitted for the sake of simplicity. Of these five conductive connections C1 to C5, three conductive connections C1 to C3 are used as bus interfaces for connecting source synchronous bus lines 25a, 25b, 25c formed on the substrate 22 and for connecting source synchronous bus lines 35a, 35b, 35c formed on the substrate 32. The remaining two through conductors 11d, 11e are used for forming the conductive connections C4, C5 as each bus interface for connecting differential signal lines 26a, 26b formed on the substrate 22 and for connecting differential signal lines 36a, 36b formed on the substrate 32.

The foregoing lines 25a, 25b, 25c, 26a, 26b, 35a, 35b, 35c, 36a, 36b are each formed of a wiring pattern formed on the substrates 22, 32, respectively. The foregoing source synchronous bus lines 25a, 25b, 25c and differential signal lines 26a, 26 formed on the substrate 22 each makes a connection between the semiconductor chip 21 and the solder balls 23. The foregoing source synchronous bus lines 35a, 35b, 35c and differential signal lines 36a, 36b formed on the substrate 32 each makes a connection between the semiconductor chip 31 and the solder balls 33.

The source synchronous bus lines 25a, 25b, 25c formed on the substrate 22 and the source synchronous bus lines 35a, 35b, 35c formed on the substrate 32 are connected via three through conductors 11a to 11c forming the foregoing three conductive connections C1 to C3 provided in the inter-chip connection part V0. The differential signal lines 26a, 26b formed on the substrate 22 and the differential signal lines 36a, 36b formed on the substrate 32 are connected via two through conductors 11d and 11e forming the foregoing two conductive conductors C4, C5 provided in the inter-chip connection part V0. In this way, the BGA components 20 and 30 are mutually connected via the substrates 22 and 32 mounted on both surfaces S1 and S2 through a main transmission line, that is, by source synchronous bus and differential signal lines, and thus, high-speed signal or data transmission is enabled.

In this case, the foregoing lines have electrically equivalent delay and wiring length. Thus, the source synchronous bus lines 25a, 25b, 25c formed on the substrate 22 have electrically equivalent delay and wiring length with the source synchronous bus lines 35a, 35b, 35c formed on the substrate 32. Further, the differential signal lines 26a, 26b formed on the substrate 22 and the differential signal lines 36a, 36b formed on the substrate 32 have electrically equivalent delay and wiring length.

Each of the element lines forming the synchronous bus on the respective substrates 22, 32 must be designed to have mutual delay zero. Namely, an electrical wiring length Td of the synchronous bus on the substrate 22 is set to be equivalent (Td=line 25a=line 25b=line 25c). Likewise, an electrical wiring length Td of the synchronous bus on the substrate 32 is equivalent (Td=line 35a=line 35b=35c).

The differential signal lines 26a, 26b formed on the substrate 22 have each electrically equivalent delay (Tddiff) for removing a common normal mode noise (Tddiff=line 26a=line 26b). Likewise, the differential signal lines 36a, 36b formed on the substrate 32 have each electrically equivalent delay (Tddiff=line 36a=line 36b).

According to the foregoing inter-chip structure using the lines on the substrates 22, 32 provided as a main transmission line, it is possible to reduce delay between buses of components mounted on the printed wiring board 10 to the minimum limit. For example, high-speed transmission lines including high-speed bus are easily mountable using PCI-Express and SATA (Serial=ATA) as a target.

In addition, according to the foregoing inter-chip structure using the substrates 22, 32 as a main transmission liner there is no need of controlling wiring and impedance for aligning delay on the high-speed transmission line in the printed wiring board 10. Thus, this serves to further improve a wiring mounting density of the printed wiring board 10. Therefore, a system design including a printed wiring board design is simplified, and low cost is expected.

FIGS. 3 to 6 each shows various structures of through conductors 11 provided in the inter-chip connection part of the printed wiring board 10. Even if any of the through conductors 11 shown in FIGS. 3 to 6 are used, inter-chip connection using the substrates as a main transmission line according to the first embodiment may be achieved.

A through conductor 11 shown in FIG. 3 has the following structure. Specifically, both ends of an interlayer via (hole) IVH are provided with a micro via μvia in the board 10. Component mounting pads Pa and Pb are provided on the micro via μvia. Though not shown in FIG. 3, solder balls 23 and 33 of the substrates 22 and 32 shown in FIG. 1 may be soldered to the component mounting pads Pa and Pb, respectively.

A through conductor 11 shown in FIG. 4 has the following structure. Specifically, a plurality of micro vias μvia are stacked linearly in the thickness direction over the entire layer of the printed wiring board 10 to form a through via. Both ends of each stacked micro vias μvia are provided with component mounting pads Pa and Pb, respectively.

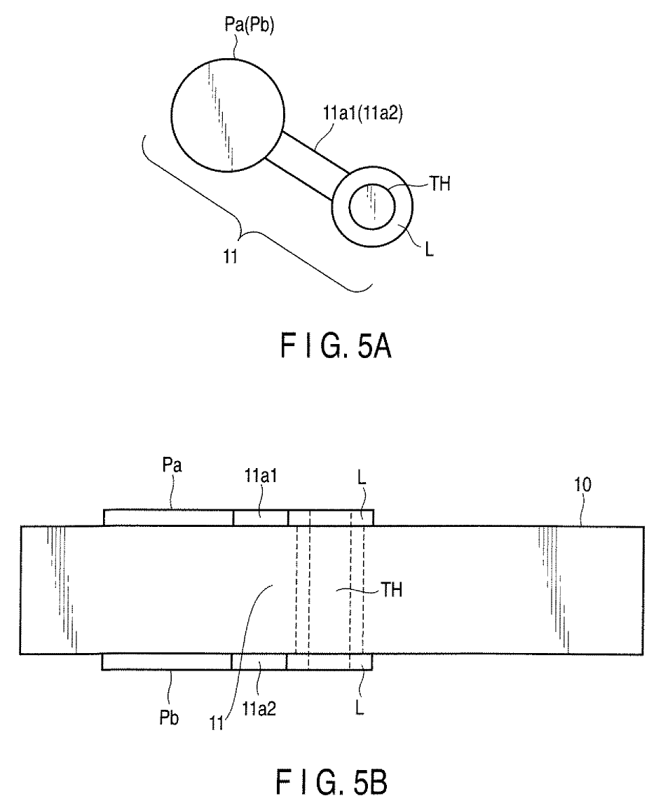

A through conductor 11 shown in FIGS. 5A and 5B has the following structure. Specifically, the printed wiring board 10 is formed with a through hole TH. Component mounting pads Pa and Pb are positioned in the vicinity of both ends of the through holes TH of the printed wiring board 10. The component mounting pads Pa, Pb and through hole lands L are connected via connection patterns 11a and 11b on both surfaces of the board 10. According to the foregoing structure, the electrical wiring lengths between the through hole TH and the component mounting pads Pa, Pb are equivalent, respectively. In the similar manner, with respect to all through conductors 11a to 11e provided in the inter-chip connection part V0 shown in FIG. 1 may be configured as in the case of FIGS. 5A and 5B.

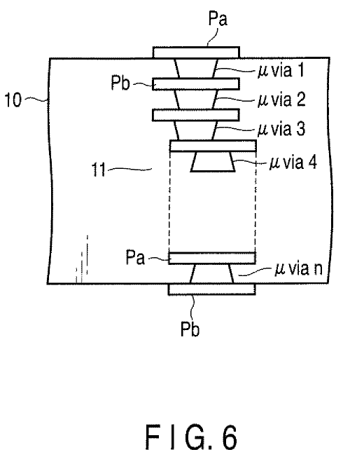

A through conductor 11 shown in FIG. 6 has the following structure. Specifically, in the case of FIG. 4, all micro vias μvia are stacked linearly in the thickness direction over the entire layer of the printed wiring board 10 to form the through via 11. However, in this case of FIG. 6, the following structure is employed to have a non-linear structure. In other words, the stacked via structure is shifted in a given position in the inner layer. Thus, component mount pads Pa and Pb are arranged asymmetrically with respect to the thickness direction of the printed wiring board 10. In this case, upper three micro vies μvia1 to μvia3 are arranged in a linear structure and the fourth micro via μvia4 is shifted from the third micro via μvia3 for a predetermined distance in the lateral direction parallel to the surfaces of the board 10. Then, the fourth micro via μvia4 to the n-th micro via μvian are linearly arranged as shown in the figure.

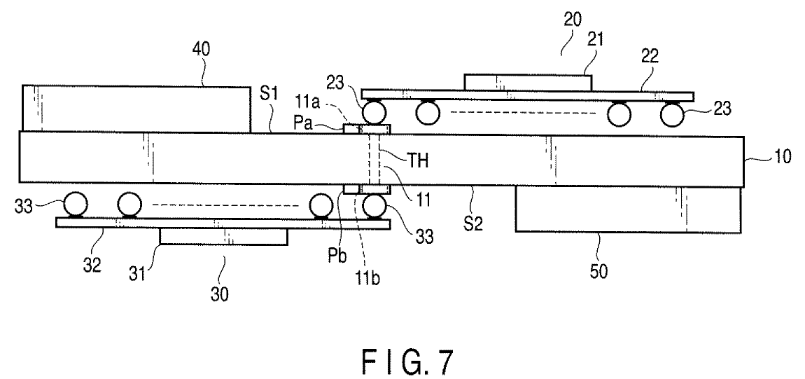

FIG. 7 relates to a modification of the printed wiring board structure according to the foregoing first embodiment.

According to the printed wiring board structure shown in FIG. 7, the following structure is provided in addition to the printed wiring board structure according to the first embodiment shown in FIG. 1. Specifically, circuit components 40 and 50 related to each circuit operation of the BGA components 20 and 30 are mounted on areas in the component mounting surfaces S1, S2 that the BGA components 20 and 30 of the printed wiring board 10 are not mounted. The circuit component 40 is a circuit module comprising a de-coupling capacitor and a power circuit for the BGA components 20 and 30. The circuit component 50 is an input/output module such as a memory slot and a high-speed bus connector.

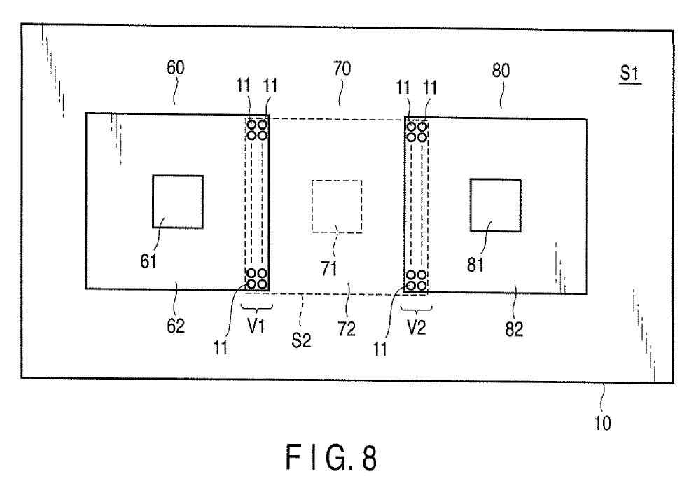

FIG. 8 shows another modification of the printed wiring board structure according to the foregoing first embodiment.

The printed wiring board structure shown in FIG. 1 has two chip sets, that is, BGA components 20 and 30. On the contrary, the printed wiring board structure shown in FIG. 8 has three chip sets, that is, semiconductor packages 60, 70 and 80. In this case, these semiconductor packages 60, 70 and 80 are mounted on component mounting surfaces S1 and S2 of the printed wiring board 10. Specifically, substrates 62, 82 are mounted on one surface S1 and a substrate 72 is mounted on another surface S2 so that the substrates 62 and 72 and substrates 72 and 82 are partially overlapped via the printed wiring board 10. These substrates further are conductively connected (soldered) to the through conductors 11 arrayed in inter-chip connection parts V1, V2 in a state that linearly arranged positional relationship is established.

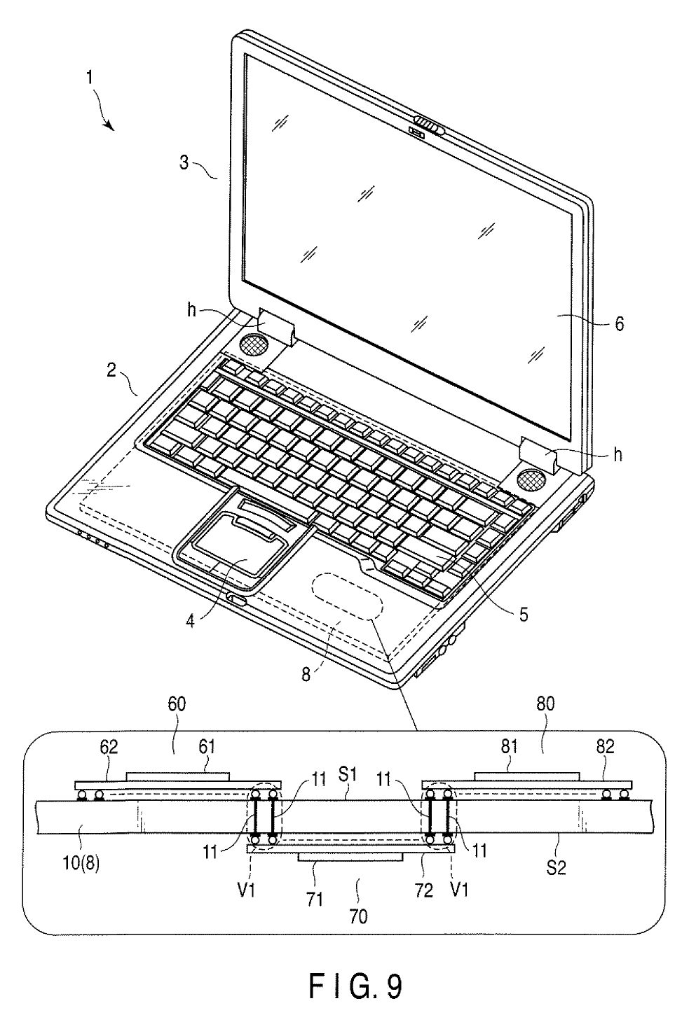

In the printed wiring board structure shown in FIG. 8, the inter-chip connection parts V1, V2 each has the same structure as the inter-chip connection part V0 of the first embodiment. Thus, in FIG. 8, the structure of the inter-chip connection parts V1, V2 is simply shown. The mounting arrangement of the semiconductor packages 60, 70 and 80 on the component mounting surfaces S1, S2 of the printed wiring board 10 is shown in FIG. 9.

According to the printed wiring board structure shown in FIG. 8, an inter-chip connection structure using the substrates as a main transmission line is provided between semiconductor packages 60, 70 and between packages 70 and 80 mounted on the printed wiring board 10. This serves to reduce delay through the semiconductor packages 60, 70 and 80 mounted on the printed wiring board 10 to the minimum limit. Therefore, for example, high-speed transmission lines including high-speed bus are easily mountable using PCI-Express and SATA (Serial-ATA) as a target.

FIG. 9 relates to a second embodiment of the present invention.

According to the second embodiment, an electronic apparatus is configured using a circuit board having the printed wiring board structure shown in FIG. 8 according to the modification of the first embodiment. FIG. 9 shows an embodiment of the present invention applied with the printed wiring board structure shown in FIG. 8 according to the modification of the first embodiment to a small-sized electronic apparatus such as handy type portable computer.

As shown in FIG. 9, a main body 2 of a portable computer 1 is attached with a display housing 3, which is freely rotatable via hinge mechanisms h. The main body 2 is provided with a control panel such as a pointing device 4 and a keyboard 5. The display housing 3 is provided with a display device 6 such as an LCD, for example.

The main body 2 is further provided with a circuit board (mother board) 8 having a built-in control circuit for controlling the foregoing control panel including the pointing device 4 and keyboard 5. The circuit board 8 may be realized using the printed wiring board structure shown in FIG. 8.

The circuit board 8 is composed of a multi-layer structure printed wiring board 10, three chip sets, that is, three semiconductor packages 60, 70 and 80. More specifically, the printed wiring board 10 has front and back component mounting surfaces S1, S2. The printed wiring board 10 further has inter-chip connection parts V1, V2 including a plurality of through conductors 11 penetrating through the board 10 between the foregoing component mounting surfaces S1 and S2. The foregoing three semiconductor packages 60, 70 and 80 are mounted on the foregoing component mounting surfaces S1, S2 in a state that they are partially overlapped via the inter-chip connection parts V1, V2. The chip sets, that is, semiconductor packages 60, 70 and 80 are mounted on the component mounting surfaces S1, S2 of the printed wiring board 10. In this case, a substrate 62 and a substrate 72 and the substrate 72 and a substrate 82 are partially overlapped via the printed wiring board 10 in a state that a linearly arranged positional relationship is established. Connection terminals of these substrates 62, 72 and 82 are conductively connected (soldered) to through conductors 11 arrayed in the inter-chip connection parts V1, V2. Incidentally, the inter-chip connection parts V1, V2 each has the same structure as the inter-chip connection part V0 described in the first embodiment.

In the circuit board 8 shown in FIG. 9, an inter-chip connection structure using the substrates as a main transmission line is provided between semiconductor packages 60, 70 and 80. In this way, it is possible to reduce interbus delay between semiconductor packages 60, 70 and 80 to the minimum limit. For example, a high-speed transmission line including a high-speed bus is easily mountable using PCI-Express and SATA (Serial-ATA) as a target. In addition, the inter-chip connection structure is provided using the substrates 62, 72 and 82 of the semiconductor packages 60, 70 and 80. Thus, there is no need of controlling wiring and impedance for aligning delay on the high-speed transmission line in the printed wiring board 10. Therefore, a system design including a printed wiring board design is simplified, and low cost is realized.

According to the foregoing embodiments, the BGA component is given as one example of the semiconductor package 10; however, the present invention is not limited to the BGA component. For example, the foregoing embodiments of the present invention are applicable to an area array type semiconductor package such as land grid array (LGA) and pin grid array (PGA). In addition, an overlapping degree between substrates on both surfaces thereof and overlapping position are not limited to illustrations. Various modifications may be made without departing from the scope of the present invention.

While certain embodiments of the invention have been described, there embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

What is claimed is:

1. A printed wiring board structure comprising:
first and second semiconductor packages each including a substrate having one surface mounted with a semiconductor chip and the other surface mounted with a plurality of arrayed external connection electrodes; and
a printed wiring board including first and second component mounting surfaces having a relationship given as front and back surfaces and an inter-chip connection part provided at one portion thereof, the inter-chip connection part being provided with a plurality of arrayed through conductors penetrating through the first and second component mounting surfaces,
wherein the substrates of the first and second semiconductor packages are arranged on the printed wiring board in a positional relationship such that the substrates mounted on the component mounting surfaces are partially overlapped via the printed wiring board, the external connection electrodes provided on the substrates are arrayed on the overlapped portion and are conductively connected to the through conductors arrayed in the inter-chip connection part, and the first semiconductor package is mounted on the first component mounting surface while the second semiconductor package is mounted on the second component mounting surface.

2. The structure according to claim 1, wherein each of the external connection electrodes arrayed at the overlapped portion of the substrates is conductively connected to the through conductor arrayed in the inter-chip connection part via solder balls.

3. The structure according to claim 1, wherein the printed wiring board has a multi-layer structure, and a through conductor arrayed in the inter-chip connection part is configured with interlayer through vias penetrating through the printed wiring board between the first and second component mounting surfaces.

4. The structure according to claim 1, wherein the printed wiring board has a multi-layer structure, and the through conductors each arrayed in the inter-chip connection part is composed of a through hole and a plurality of vias.

5. The structure according to claim 1, wherein the inter-chip connection part is configured as a bus connection interface between the first and second semiconductor packages.

6. The structure according to claim 1, wherein the first and second semiconductor packages have substrates which are linearly arranged on the first and second component mounting surfaces.

7. The structure according to claim 6, wherein the first and second semiconductor packages are each a mirror image pin assignment structure chip set.

8. An electronic apparatus comprising:
an electronic apparatus body; and
a circuit board built in the electronic apparatus body,
the circuit board comprising:
first and second semiconductor packages each including a substrate having one surface mounted with a semiconductor chip and the other surface mounted with a plurality of arrayed external connection electrodes; and
a printed wiring board including first and second component mounting surfaces having a relationship given as front and back surfaces and an inter-chip connection part provided at one portion thereof, the inter-chip connection part being provided with a plurality of arrayed through conductors penetrating through the first and second component mounting surfaces,
wherein the substrates of the first and second semiconductor packages are arranged on the printed wiring board in a positional relationship such that the substrates mounted on the component mounting surfaces are partially overlapped via the printed wiring board, the external connection electrodes provided on the substrates are arrayed on the overlapped portion and are conductively connected to the through conductors arrayed in the inter-chip connection part, and the first semiconductor package is mounted on the first component mounting surface while the second semiconductor package is mounted on the second component mounting surface.
